(19) United States
(12) Patent Application Publication
(10) Pub. No.: US 2023/0197643 A1
(43) Pub. Date: Jun. 22, 2023

(54) METAL INSULATOR METAL (MIM) CAPACITORS WITH PYROCHLORE-BASED INSULATORS FOR INTEGRATED CIRCUIT DIE & PACKAGES

(71) Applicant: Intel Corporation, Santa Clara, CA (US)

(72) Inventors: Elijah Karpov, Portland, OR (US); Sou-Chi Chang, Portland, OR (US); Scott Clendenning, Portland, OR (US); Matthew Metz, Portland, OR (US)

(73) Assignee: Intel Corporation, Santa Clara, CA (US)

(21) Appl. No.: 17/560,062

(22) Filed: Dec. 22, 2021

(51) Int. Cl. H01L 23/64; H01L 23/528; H01L 21/02

(52) U.S. Cl. CPC H01L 23/642; H01L 21/0228; H01L 23/5286

(57) ABSTRACT

IC die and/or IC die packages including capacitors with a pyrochlore-based insulator material. The pyrochlore-based insulator material comprises a compound of a species A and a species B, each comprising one or more rare earths or metals. In the pyrochlore-based insulator material, oxygen content is advantageously more than three times and less than four times the amount of either of species A or B with crystalline pyrochlore phases having the composition A₂B₂O₇. Within a capacitor, the pyrochlore-based insulator may be amorphous and/or may have one or more crystalline phases. The pyrochlore-based insulator has an exceedingly high relative permittivity of 50-100, or more. The pyrochlore-based insulator material may be deposited at low temperatures compatible with interconnect metallization processes practiced in IC die manufacture as well as IC die packaging.

### BACKGROUND

Integrated circuit (IC) devices often require capacitors for various electronic functions (e.g., bit-cells in electronic memory, signal conditional filters, and A/C coupling in power delivery, etc.). A MIM capacitor can be utilized in a variety of applications such as microprocessor units, in radio frequency circuits and in other analog integrated circuit devices. A capacitor may, for example, provide a bypass path for transient currents in an IC that might otherwise damage active electronic devices such as transistors. A capacitor can also provide power to an integrated circuit and keep the power supply voltage stable absorbing excess electrical energy (charge) flowing through the integrated circuit.

Conventional silicon-based dielectric materials, such as SiO₂ and SiON have long been utilized as the thin film insulator material of metal-insulator-metal (MIM) capacitors fabricated in either an integrated circuit (IC) die or IC die packaging. For scaling and performance, it is desirable for an IC capacitor to have a large capacitance per unit area. A larger capacitance can be obtained when an insulator in a MIM capacitor has a higher relative permittivity, or dielectric constant.

Because silicon-based dielectric materials have a relative permittivity below 10, metal-based dielectrics known to be suitable for IC devices, such as certain oxides of hafnium, aluminum or zirconium, may be utilized in some MIM capacitors for the sake of their higher values of relative permittivity (e.g., 25-35). While these materials are an improvement over silicon-based insulators, it remains difficult to fabricate capacitors having sufficiently large total capacitance values. Also, many such insulator materials rely on high temperature processing and so may not be suitable for IC applications where processing temperatures need to remain low. For example, many IC die packaging processes that employ organic dielectric materials limit processing to temperatures below 250° C.

Insulator materials and associated deposition techniques that can address one or more of the limitations in relative permittivity or thermal processing are therefore advantageous for high performance MIM capacitor applications in IC devices.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures1 to indicate corresponding or analogous elements. In the figures:

FIG. 1A is a flow diagram illustrating methods for forming a high-performance MIM capacitor in an IC die or IC die package, in accordance with some embodiments;

FIG. 1B is a flow diagram illustrating methods of depositing a pyrochlore-based insulator material layer, in accordance with some embodiments;

FIGS. 2A, 2B, 2C and 2D illustrate cross-sectional views of a high-performance MIM capacitor evolving as the methods illustrated in FIG. 1A are practiced, in accordance with some embodiments;

FIG. 3 is a flow diagram illustrating methods for integrating high-performance MIM capacitors into an IC die, in accordance with some embodiments;

FIG. 4 is a cross-sectional view of an IC die including high-performance MIM capacitor within either a substrate or metallization level of an IC die, in accordance with some embodiments;

FIG. 5 is a flow diagram illustrating methods for integrating high-performance MIM capacitors into an IC die package, in accordance with some embodiments;

FIGS. 6A, 6B, 6C and 6D illustrate cross-sectional views of a high-performance MIM capacitor evolving as the methods illustrated in FIG. 5 are practiced, in accordance with some embodiments;

FIG. 7 illustrates a mobile computing platform and a data server machine employing an IC that includes a high-performance MIM capacitor, in accordance with some embodiments; and

FIG. 8 is a functional block diagram of an electronic computing device, in accordance with some embodiments.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

The term “adjacent” here generally refers to a position of a thing being next to (e.g., immediately next to or close to with one or more things between them) or adjoining another thing (e.g., abutting it).

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

The term “signal” may refer to at least one current signal, voltage signal, magnetic signal, or data/clock signal.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

As used throughout this description, and in the claims, a list of items joined by the term “at least one of” or “one or more of” can mean any combination of the listed terms.

Unless otherwise specified in the explicit context of their use, the terms “substantially equal,” “about equal” or “approximately equal” mean that there is no more than incidental variation between two things so described. In the art, such variation is typically no more than +/-10% of a predetermined target value.

IC die and/or IC die packages including capacitors with a pyrochlore-based insulator are described herein. “Pyrochlore-based” insulators comprise a compound of oxygen and two species A, and B, each of which may comprise one or more rare earths or metals. In contrast to perovskite oxides, which comprise a compound of ABO₃ (e.g., BaTiO₃, SrTiO₃, BaSrTiO₃), pyrochlore-based oxides have more than three times the amount of oxygen as either of the A or B species. Hence, pyrochlore-based compositions in accordance with embodiments herein are generally richer in oxygen than perovskite compositions. An IC capacitor insulator in accordance with embodiments herein has an oxygen content that is less than four times the amount of either of the species A or B with pyrochlore-based compounds advantageously able to enter pyrochlore crystalline phases when their chemical composition is A₂B₂O₇.

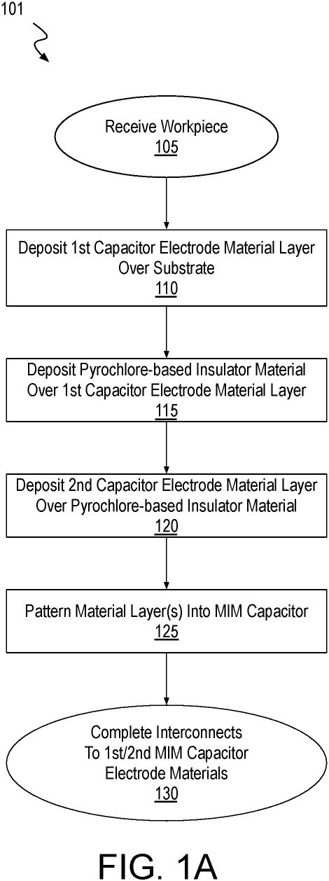

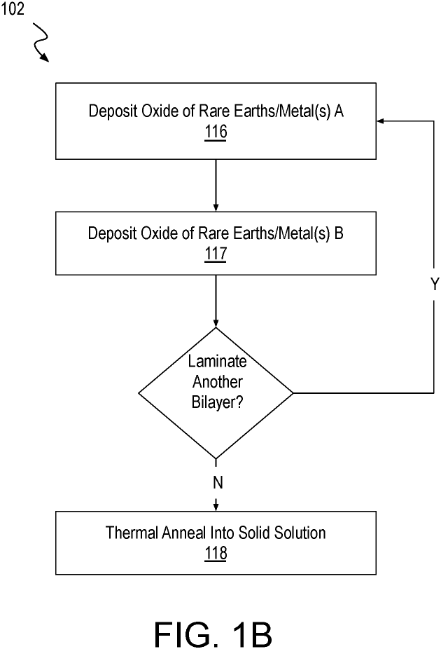

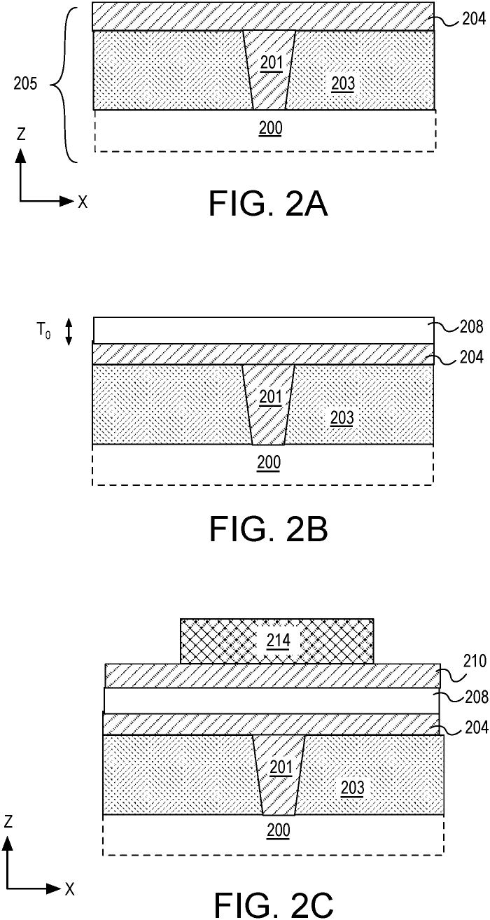

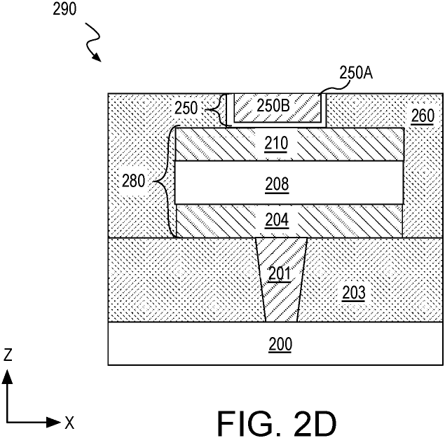

FIG. 1A is a flow diagram illustrating methods 101 for forming a high-performance MIM capacitor in an IC die or IC die package, in accordance with some embodiments. FIGS. 2A-2D illustrate cross-sectional views of a high-performance MIM capacitor evolving as methods 101 are practiced, in accordance with some exemplary embodiments.

Referring first to FIG. 1A, methods 101 begin at block 105 where a workpiece is received. In some embodiments, the workpiece received at block 105 is a wafer suitable for IC die fabrication. In some other embodiments, the workpiece received at block 105 is a panel or reconstituted die carrier suitable for IC die packaging. Methods 101 continue at block 110 where one or more first (lower) capacitor electrode material layers are deposited over a substrate surface. The deposition process employed at block 110 may vary with the material layer compositions. In some examples, capacitor electrode material layers are deposited with at least one of physical vapor deposition (PVD), atomic layer deposition (ALD), metal-organic chemical vapor deposition (MOCVD) or CVD.

In the example illustrated in FIG. 2A, an IC die portion 205 includes a lower capacitor electrode material layer 204 over a substrate 200. Substrate 200 is illustrated in dashed line as its structure may vary dramatically depending on the application of a particular capacitor within an IC die. For example, substrate 200 may have any number of material layers of any composition and/or microstructure. Substrate 200 may, for example, further include part of a workpiece substrate (e.g., a large format semiconductor wafer) that is to become an IC chip, and may further include at least one active device layer (e.g., further including transistors). Substrate 200 may also include one or more interconnect metallization levels interconnecting transistors into an integrated circuit. IC die portion 205 further includes a conductive interconnect 201 between electrode material layer 204 and substrate 200. In the example, conductive interconnect 201 is embedded within a dielectric 203. Dielectric 203 may be silicon dioxide, silicon nitride, silicon carbide, or any known low-k dielectric, for example.

Electrode material 204 may comprise one or more conductive material layers. In some embodiments, electrode material 204 includes a seed layer, which may be lowermost material layer that is in contact with interconnect 201 and dielectric material 203, or which may be an uppermost layer of electrode material 204. A seed layer may have any material composition that promotes desirable microstructure within other layers of a MIM capacitor structure. Tantalum is one exemplary seed layer material, but other metals, such as tungsten, may also be suitable. In further embodiments, electrode material 204 comprises a metal, for example having crystallinity that is compatible with pyrochlore insulator materials. In some embodiments, electrode material 204 comprises a metal having FCC or hexagonal crystallinity, such as one or more of titanium, ruthenium or iridium.

In some embodiments, electrode material 204 comprises a predominantly carbon (i.e., more than 50 at. % carbon) layer. Such a carbonaceous electrode layer may be substantially pure carbon (i.e., more than 95 at. % carbon). In exemplary embodiments, the carbonaceous electrode layer is graphitic carbon. Graphitic carbon can be more specifically characterized as sp2 carbon, which distinguished from sp3 carbon also known as diamondlike carbon (DLC). While DLC is generally a dielectric with high electrical resistivity, the graphitic carbon advantageously has an electrical resistivity less than 100-300 mΩ-cm. Although a graphitic carbon layer may be anywhere within electrode material 204, in some embodiments an uppermost surface of electrode material 204 comprises graphitic carbon.

Returning to FIG. 1A, methods 101 continue at block 115 where a pyrochlore-based insulator material is deposited over the capacitor electrode material layer(s) deposited at block 110. In some embodiments, a pyrochlore-based insulator is deposited by PVD where a target having the desired chemical composition (e.g., A₂B₂O₇) is sputtered for a desired duration. The PVD process may be performed with the workpiece cold (e.g., room temperature) or at an elevated temperature (e.g., 250-400° C., or more), which may promote a particular crystal texture and/or dominant phase within the insulator material. The sputtered material may be thermally annealed after deposition to promote crystallization of one or more crystalline (e.g., pyrochlore) phases. In alternative embodiments, the pyrochlore-based insulator is formed by ALD or direct liquid injection (DLI) MOCVD. The deposited material may then be similarly annealed, for example to form a solid solution of more homogeneous composition, which may enter one or more crystalline phases.

FIG. 1B is a flow diagram illustrating some exemplary methods of depositing a pyrochlore-based insulator material layer. In contrast to a sputtering technique, methods 102 generally entail forming a lamination or layered structure of binary components. At block 116, a first material layer comprising predominantly oxygen and one or more rare earths/metals A is deposited, for example with either ALD or MOCVD. At block 117, another material layer comprising oxygen and one or more rare earths/metals B is deposited, for example with either ALD or MOCVD. This two phase cyclic deposition process may be repeated any number of times to arrive at a desired laminate thickness. Methods 102 are then completed with a thermal anneal at block 118.

Block 118 may comprise a furnace anneal, a flash anneal, or laser anneal, for example. A furnace anneal (or other anneal) may be performed in a forming gas or other ambient at a predetermined temperature and duration sufficient to form intermix the laminate layers of binary oxide. Notably, pyrochlore-based insulators can crystallize at lower temperatures than perovskites, and in some embodiments, the anneal at block 118 is performed at a temperature in the range of 200-450° C.

FIG. 2B further illustrates an example where a pyrochlore-based insulator material layer 208 has been deposited on electrode material layer 204. As noted above, pyrochlore-based insulator material layer 208 comprise a compound of oxygen, a species A comprising one or more first rare earths or metals, and a species B comprising one or more second rare earths or metals. Insulator material layer 208 is referred to herein as “pyrochlore-based” because species A and B need not include niobium (Nb) as in the pyrochlore mineral, but instead may comprise other rare earths or metals. Also, “pyrochlore” is often employed as a generic term for the pyrochlore crystal structure, and pyrochlore-based insulator material layer 208 need not be crystalline and may instead be substantially amorphous.

Each species A and B may include one or more rare earths, such as scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), ytterbium (Yb) or lutetium (Lu). Each species A and B may also include one or more transition metals (IUPAC Groups 3-12 of the periodic table), or post-transition metals including bismuth (Bi), tin (Sn), gallium (Ga), lead (Pb), titanium (Ti), and indium (In).

Pyrochlore-based insulator materials in accordance with embodiments herein have more than three times the amount of oxygen as either of the species A or B, but is advantageously less than four times the amount of either of the species A or B. In some exemplary embodiments, the atomic ratio of A:O is approximately equal to the atomic ratio of B:O. For advantageous embodiments where pyrochlore-based insulator material layer 208 has the chemical composition A₂B₂O₇ with A:O and B:O both being 2:7, pyrochlore-based insulator material layer 208 can become (poly)crystalline. At this composition, the insulator material may enter pyrochlore crystalline phases where relative permittivity of the material increases significantly, for example to values of 100, or more. If polycrystalline, insulator material layer 208 may have a particular crystal texture and include one or more crystalline phases (e.g., pyrochlore crystallinity). Although insulator material layer 208 is advantageously (poly)crystalline material for highest relative permittivity, the inventors have found pyrochlore-based insulator material layer 208 can have a high relative permittivity of over 50 even when amorphous.

In some exemplary embodiments, species A or species B comprises Bi, Zn or Nb. In some of these examples, at least one of species A or B comprises Mg, Cu, Ni, Sc, In or Ta. In some of these examples, both of A and B comprises one of Bi, Zn or Nb. Notably, each of species A and species B may include more than one of the rare earths or metals listed above. For example, in some embodiments at least one of species A or species B comprises two of Bi, Zn or Nb. In some of these examples where species A comprises Bi, B comprises two or more of Ng, Cu, Zn, Sc, In, Nb, or Ta. Since Bi has a ³⁺ oxidation state, such Bi-based embodiments may have the general chemical form of Bi₂(2/3B ²⁺ , 4/3 B⁵⁺ )O₇ or Bi₂(B³⁺, B⁵⁺ )O₇. Exemplary species B having a ²⁺ oxidation sate include Mg, Cu, Zn, and Ni. Exemplary species B having a ³⁺ oxidation sate include Sc and In, and exemplary species B having a ⁵⁺ oxidation sate includes Nb and Ta.

Hence, various rare earths/metals may be included in a pyrochlore-based insulator composition having the target stoichiometric ratio of A₂B₂O₇. To illustrates this principle, in one specific example pyrochlore-based insulator material layer 208 is (Bi_{1.5}Zn_{0.5})(Zn_{0.5}Nb_{1.5})O₇, where species A includes Bi and Zn and species B comprises Zn and Nb. Although pyrochlore-based insulator material layer 208 may include other minority constituents, such dopants are advantageously only in trace impurity levels (e.g., <1e17 atoms/cm³).

Returning to FIG. 1A, methods 101 continue at block 120 where another capacitor electrode material layer is deposited over the pyrochlore-based insulator deposited at block 115. Any of the deposition techniques described above for block 110 may be practiced at block 115 to deposit one or more of the electrode materials described above. Methods 101 then continue with patterning one or more material layers of the capacitor material stack at block 125, for example according to any thin film patterning techniques. Methods 101 then complete at output 130 where interconnects to the MIM capacitor electrode materials are fabricated, completing integration of the MIM capacitor into the IC device. The IC device may then be completed with any processing known in the art, which may include one or more thermal anneals during which the pyrochlore-based insulator material, as a solid solution, may undergo phase changes into a microstructure having greater crystallinity than the insulator material had as deposited.

In the example illustrated in FIG. 2C electrode material layer 210 may include one or more material layers, such as any of those described above for electrode material layer 204. In some embodiments, electrode material layer 210 is predominantly a metal, such as one or more of Ti, W, Cu, Ru, or Ir. In other embodiments, electrode material layer 210 comprises a graphitic material (e.g., substantially pure carbon) layer, for example in contact with insulator material layer 208. As further shown in FIG. 2C, a mask 214 formed on upper electrode material layer 210 may define any polygon area and position of a MIM capacitor within an IC device, for example relative to interconnect 201. Mask 214 may be formed with any lithographic process(es) as embodiments are not limited in this respect.

FIG. 2D illustrates an IC device portion 290 following the patterning of the capacitor material layer stack, for example with one or more plasma etch processes. The etch process(es) define sidewalls into the various material layers 210, 208 and 204 to define MIM capacitor 280. FIG. 2D further illustrates an example where an upper-level interconnect 250 has been fabricated in contact with the electrode material layer 210. In this example, interconnect 250 includes an adhesion layer/diffusion barrier 250A (e.g., tantalum, tantalum nitride or ruthenium) in contact with electrode material layer 210. A fill metal 250B (e.g., cobalt, tungsten copper) has been deposited on adhesion layer/diffusion barrier 250A and a dielectric material 260 encapsulates MIM capacitor 280.

In addition to MIM capacitors, an IC may also include metal-insulator-semiconductor (MIS) capacitors that include a pyrochlore-based insulator material layer, for example substantially as described above. In some embodiments, a pyrochlore-based insulator material layer is integrated into a field effect transistor (FET). Accordingly, capacitor structures including a pyrochlore-based insulator material, such as those described above, may be integrated into a wide variety of IC devices.

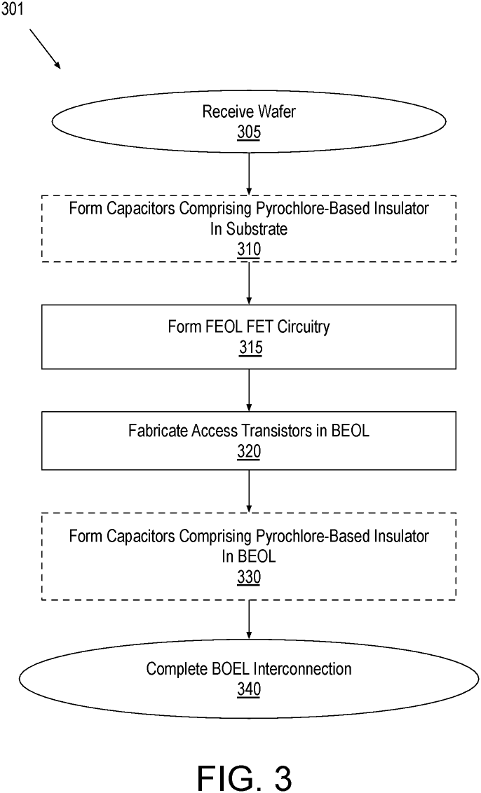

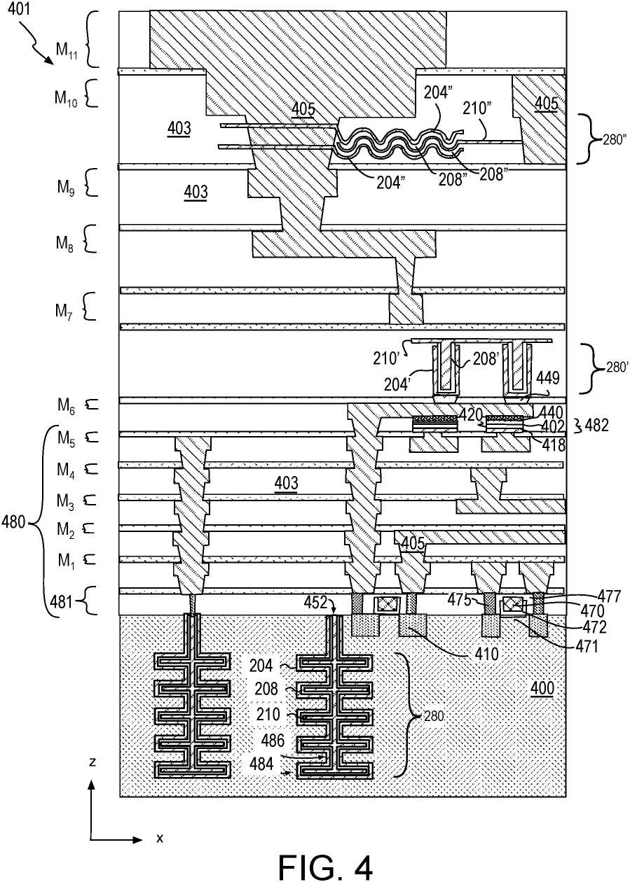

FIG. 3 is a flow diagram illustrating methods 301 for integrating high-performance MIM capacitors into an IC die, in accordance with some embodiments. Methods 301 begin at input 305 where any wafer suitable for monolithic IC fabrication is received. FIG. 4 is a cross-sectional view of an IC die portion 401 that may be fabricated according to methods 301 to include high-performance MIM capacitors within either a substrate or metallization level, in accordance with some embodiments.

In the example shown in FIG. 4, IC die substrate 400 comprises a monocrystalline semiconductor material such as, but not limited to, predominantly silicon (e.g., substantially pure Si) material, predominantly germanium (e.g., substantially pure Ge) material, or a compound material comprising a Group IV majority constituent (e.g., SiGe alloys, GeSn alloys). In other embodiments, IC die substrate 400 is a Group III-N material comprising a Group III majority constituent and nitrogen as a majority constituent (e.g., GaN, InGaN). Other embodiments are also possible, for example where IC die substrate 400 is a Group III-V material comprising a Group III majority constituent and a Group IV majority constituent (e.g., InGaAs, GaAs, GaSb, InGaSb).

Returning to FIG. 3, methods 301 continue at block 310. Block 310 is optional, as denoted by dashed lines, but is practiced to embed a high performance MIM capacitor comprising a pyrochlore-based insulator within the IC die substrate. Various deep via capacitor fabrication techniques may be practiced at block 310. FIG. 4 illustrates one example of an ultra MIM structure comprising a via 452 that was first etched into substrate 400. IC die substrate 400 includes multiple material bi-layers. Each bi-layer may have, for example, different impurity doping (e.g., n-type and p-type bi-layers). In other embodiments, each bi-layer comprises differing amounts of Ge (e.g., SiₓG₁₋ₓ and Si bi-layers). The bi-layer structure is exploited by selectively recess etching one type of layer of each bi-layer exposed by via 452. The sidewall of via 452 is therefore expanded to a larger diameter 484 for one of the substrate layers that is etched while the sidewall through unetched substrate layers retains a smaller diameter 486. The undulating sidewall of via 452 is then lined with electrode material 204, pyrochlore-based insulator material 208, and electrode material 210, thereby embedding MIM capacitor 280 within IC die substrate 400. In exemplary embodiments, pyrochlore-based insulator material 208 is advantageously deposited by ALD for superior conformality on the undulating sidewall of via 452, and precise thickness control down to 5-10 nm, for example.

Returning to FIG. 3, methods 301 continue at block 315 where front-end-of-line (FEOL) fabrication processes are practiced to form logic (e.g., ASIC) circuitry. Any FEOL process(es) may be practiced at block 315. In the example illustrated in FIG. 4, FEOL circuitry 480 includes field effect transistors (FETs) 481. FETs 481 employ monocrystalline semiconductor material for at least the channel semiconductor 471. FETs 481 further include a gate terminal 470 separated from channel semiconductor 471 by a gate insulator 472. Channel semiconductor 471 separates semiconductor terminals 410 (source semiconductor and drain semiconductor). Contact metallization 475 lands on semiconductor terminals 410, and is separated from gate terminal 470 by an intervening insulator 477. FETs 481 may be planar or non-planar devices. In some advantageous embodiments, FETS 481 are finFETs or stacked nanosheet transistors. FEOL circuitry 480 further includes one or more initial levels of interconnect metallization 405 embedded in dielectric material 403. In the exemplary embodiment illustrated, FEOL circuitry 480 includes metal-one (M₁), metal-two (M₂) metal-three (M₃), and metal-four (M₄) levels interconnecting FETs 481.

Returning to FIG. 3, methods 301 continue at block 320 where access transistors are fabricated over the FEOL circuitry, within a back-end-of-line (BEOL) layer of the IC die. In some embodiments, block 320 comprises fabricating TFTs. The TFTs may be planar channel devices, fin channel devices, or recessed channel devices. In the example illustrated in FIG. 4, a plurality of TFTs 482 is located over FEOL circuitry 480. Individual ones of TFTs 482 include a gate terminal (electrode) 418 separated from semiconductor layer 402 by a gate dielectric 420. In the exemplary embodiment illustrated, TFTs 482 are “bottom-gate” devices with semiconductor layer 402 deposited over gate terminal 418. Alternatively, top-gate architectures are also possible where at least gate terminal 418 is above semiconductor layer 402. Terminal contact metallization 440 lands on source and drain regions of semiconductor layer 402. TFTs 482 are coupled to a memory device bitline comprising an interconnect metallization trace within a BEOL metallization level M₆. Source terminals of TFTs 482 are electrically connected to capacitor storage nodes through interconnect metallization 449.

Semiconductor layer 402 may be a group IV semiconductor material, such as silicon (Si), germanium (Ge), and SiGe alloys. However, in some exemplary embodiments, semiconductor layer 402 comprises an oxide semiconductor comprising a metal and oxygen. An oxide semiconductor thin film can be amorphous (i.e., having no structural order), or polycrystalline (e.g., having micro-scale to nano-scale crystal grains). In some embodiments, semiconductor layer 402 comprises a tin oxide (SnOₓ), such as Tin (IV) oxide, or SnO₂. In some other embodiments, semiconductor layer 402 comprises a zinc oxide (ZnOₓ), such as Zn(II) oxide, or ZnO. Semiconductor layer 402 (or various portions thereof) may be intentionally doped, or not. Compared to intrinsic oxide semiconductor that is not intentionally doped, n-type and p-type oxide semiconductors may have a higher concentration of impurities, such as, but not limited to, one or more group III element, group V element, and/or elemental hydrogen (H), and/or oxygen vacancies. In some embodiments where semiconductor layer 402 comprises ZnOₓ, the dopants may include In and Ga. In some specific examples, semiconductor layer 402 is InGaO₃(ZnO)₅, often referred to simply as IGZO.

Returning to FIG. 3, methods 301 continue at block 330 where high performance MIM capacitors are formed within a BEOL level over the cell access transistors. At block 330, pyrochlore-based insulator material is formed on at least one sidewall of a capacitor conductor. As shown in FIG. 4, each storage node interconnect metallization 449 electrically couples a first capacitor electrode material layer 204′ to a semiconductor terminal (e.g., source semiconductor) of one access transistor. MIM capacitors 280′ further include another electrode material layer 210′ that is separated from electrode material layer 204′ by an intervening pyrochlore-based insulator material 208′, which may have any of the properties described above, for example. Accordingly, the same reference numbers are employed for the high performance MIM capacitors within the memory array as introduced above to emphasize the MIM material layer compositions may be substantially the same.

MIM capacitors 280′ generally have a “trench capacitor” structure where the MIM stack is deposited into a trench for higher capacitor density than for most planar MIM architectures. In exemplary embodiments where memory capacitor structures are substantially cylindrical (e.g., a right cylinder that is open at the top), pyrochlore-based insulator material 208′ lines at least an interior sidewall of the cylinder. For such applications, pyrochlore-based insulator material 208′ is advantageously deposited by ALD for superior conformality and precise thickness control down to 5-10 nm, for example.

Returning to FIG. 3, methods 301 continue at block 330, where MIM capacitors with a pyrochlore-based insulator may be optionally introduced into BEOL metallization levels for IC die applications other than embedded memory. At block 330, any of the operations described above in the context of FIGS. 1A or 1B may be practiced to integrate a high performance MIM capacitor into an IC die architecture. For example, one or more coupling capacitors and/or power supply conditioning capacitors may include a pyrochlore-based insulator material having one or more of the properties described above. Following fabrication of such capacitors, the BEOL interconnect metallization may be completed at output 340 according to any known techniques.

In the example further illustrated by FIG. 4, a vertically interdigitated multi-plate MIM capacitor 280″ includes first electrode material layer 204″ electrically coupled to one circuit node by interconnect feature 405. A second electrode material layer 204″ is also electrically coupled by interconnect feature 405 to the same circuit node. These upper and lower electrode layers 204″ are therefore operable as one terminal of interdigitated multi-plate MIM capacitor 280″. Another interconnect feature 405 is coupled to a second circuit node and electrode material layer 210″, between the two instances of electrode material layer 204.” Pyrochlore-based insulator material layer 208″ is therefore between the interdigitated electrode material layers 204″ and 210.” Although only one electrode layer interdigitation is illustrated in FIG. 4, any number of such iterations are possible in such a vertically interdigitated multiplate capacitor as a means of increasing total capacitance. As also illustrated in FIG. 4, multi-plate MIM capacitor 280″ need not be planar, but instead may be formed over an undulating topography to increase capacitive density. In the example illustrated, material layers 204, 208 and 210 have been deposited over a material layer having a plurality of openings, perforations, or recesses and this topography induces the illustrated undulations within MIM capacitor 280″.

In accordance with some other embodiments, IC packages include an IC chip that is coupled to an electrical routing structure within a package dielectric where more high performance metal-insulator-metal (MIM) capacitors is also embedded. For such applications, the package dielectric may severely limit thermal processing so that it can be difficult to fabricate MIM capacitors from any materials other than conventional silicon-based dielectric materials (e.g., SiO₂). However, as further described below, package MIM capacitor structures comprising pyrochlore-based insulator materials may be embedded in low-temperature packing materials and then electrically coupled to the IC chip by the package interconnect features.

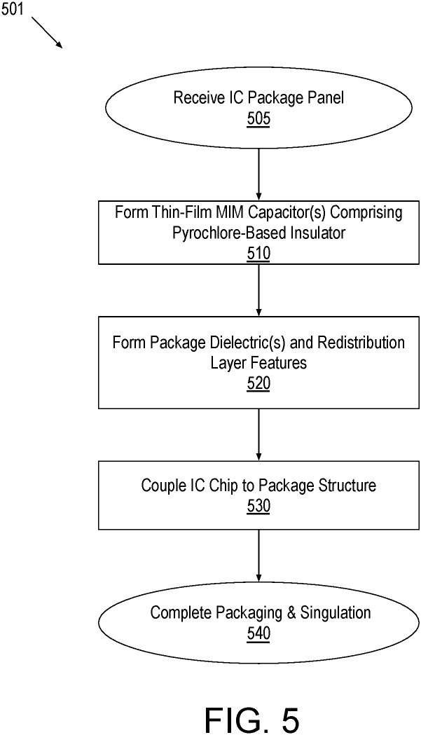

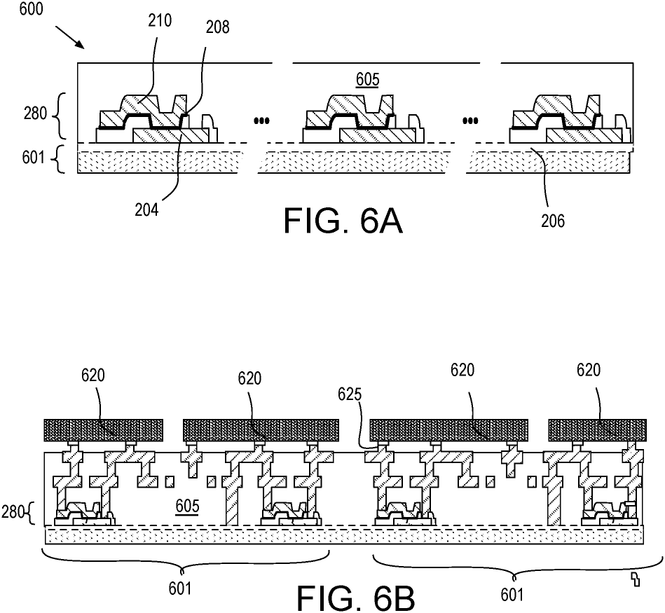

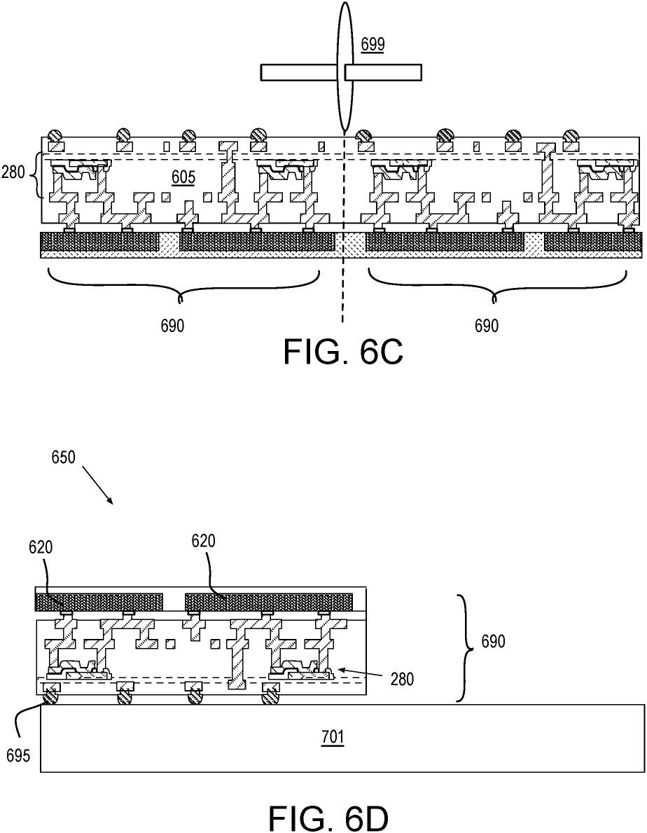

FIG. 5 is a flow diagram illustrating methods 501 for integrating such high-performance MIM capacitors into an IC die package, in accordance with some embodiments. FIGS. 6A-6C illustrate cross-sectional views of a high-performance MIM capacitor 601 evolving as the methods 501 are practiced, in accordance with some exemplary IC die packaging embodiments.

Referring first to FIG. 5, methods 501 begin at block 505 with the receipt of a packaging workpiece, for example including a panelized carrier. In an exemplary embodiment, the workpiece is substantially planar and dimensioned in thickness and lateral area to be a suitable support for panelized processing of multiple packages arrayed over the substrate. The various material layers of such a workpiece may be retained within a final singulated package, or separated from a final package as part of a sacrificial carrier.

Methods 501 continue at block 510 with the fabrication of MIM capacitors. Any number of additive or subtractive thin film processes may be practiced at block 512 to fabricate a capacitor structure including a pyrochlore-based insulator material substantially as described above. Block 510 may therefore entail the deposition of any electrode material layers and pyrochlore-based insulator material layers, for example as described in the context of FIGS. 1A and 1B. F

In the example shown in FIG. 6A, workpiece 600 includes MIM capacitor 280. A package dielectric 605 is formed over each MIM capacitor 280, at least partially embedding MIM capacitor 280 within package dielectric 605. Depending on the embodiment, package dielectric 605 may be any of a molding compound, a spin-on material, or dry film laminate material, for example. Package dielectric 605 may be introduced wet/uncured into a cast and then dried/cured. Alternatively, package dielectric 605 may be introduced as a semi-cured dry film that is deformed around MIM capacitors 280, and then fully cured.

Package dielectric 605 is advantageously an organic material, such as, an epoxy resin, phenolic-glass, or a resinous film such as the GX-series films commercially available from Ajinomoto Fine-Techno Co., Inc.). Package dielectric 605 may comprise epoxy resins (e.g., an acrylate of novolac such as epoxy phenol novolacs (EPN) or epoxy cresol novolacs (ECN)). In some specific examples, package dielectric 605 is a bisphenol-A epoxy resin, for example including epichlorohydrin. In other examples, package dielectric 605 includes bisphenol-F epoxy resin (with epichlorohydrin). In other examples, package dielectric 605 includes aliphatic epoxy resin, which may be monofunctional (e.g. dodecanol glycidyl ether), difunctional (butanediol diglycidyl ether), or have higher functionality (e.g. trimethylolpropane triglycidyl ether). In still other examples, package dielectric 605 includes glycidylamine epoxy resin, such as triglycidyl-p-aminophenol (functionality 3) and N,N,N′,N′-tetraglycidyl-bis-(4-aminophenyl)-methane (functionality 4). Such polymeric materials may decompose at elevated temperatures and therefore the pyrochlore-based insulator material may be deposited at low temperatures (e.g., < 250° C.), for example by PVD, and/or never annealed at a temperature exceeding a threshold for package dielectric 605.

Returning to FIG. 5, fabrication of package routing structures may continue with relatively low temperature processing (e.g., less than 250° C.) at block 520 where electrically conductive metallization features are formed within one or more package dielectric materials. One or more of these package metallization features may be coupled to one or more electrodes of the individual capacitor structures. Any number of levels of metallization features may be formed at block 520 with a top level terminating at features that are suitable for interconnecting with an IC die. These metallization features may be built up within package dielectric materials may be formed over a top of the MIM capacitors. For example, an overmold process, dry film lamination, or spin-on/spray-on dielectric process may be performed at block 520 to at least partially encapsulate the MIM capacitors.

At block 530, one or more IC dies are coupled to the package routing structure, for example with a first-level interconnect (FLI) chip attachment process. With the chip attachment, one or more IC chips may be electrically coupled to one or more of the package-level high-performance MIM capacitor structures through one or more of the package metallization features. Once an IC chip is attached, one or more additional package dielectric materials may be formed over a top of the IC chip and/or between the IC chips. For example, an overmold process, dry film lamination, or spin-on/spray-on dielectric process may be performed at block 530 to at least partially encapsulate the IC chip within the package.

In the example shown in FIG. 6B, IC chips 620 are attached to the package including MIM capacitors 280. In some embodiments, each IC chip 620 includes microprocessor circuitry. The microprocessor circuitry may be operable, for example, to execute a real-time operative system (RTOS). In some further embodiments, IC chip 620 is operable to execute one or more layers of a software stack that controls radio (wireless) functions. In one exemplary embodiment, IC chip 620 includes a digital baseband processor, or baseband radio processor (BBP) suitable for use within a mobile phone, or other wireless/mobile device.

In the illustrated example, two IC chips 620 are attached to each package routing structure. While such multi-chip package embodiments may be advantageous for a variety of applications, single-chip packages are also possible. Any technique known to be suitable for positioning an IC chip onto a package substrate may be employed. As one example, a pick-and-place machine may pick-and-place IC chips 620 onto the packaging workpiece. In some examples, FLI 625 comprises a solder feature. The solder features may be solder balls, for example, that may be attached according any known process such as a controlled heat treatment that may partially reflow one or more of solder flux or a solder ball. Alternatively, the solder features may be studs, pillars or microbumps comprising a conductive material (e.g., solder paste).

Returning to FIG. 5, methods 501 end at output 540 where package routing is completed in any manner that facilitates a further coupling of the package to a host component. In some exemplary embodiments describe further below, one or more material layers of the substrate are removed from the packaging workpiece and additional metallization features are formed on a side of the package routing structure opposite the IC die. Such package metallization features may terminate at an interface suitable for interconnecting the package to a host component. One or more of these features may also couple to one or more of the MIM capacitors and/or may couple to one or more of the metallization features formed at block 530. Following completion of the package, the packaging workpiece may be singulated from the panel to generate singular IC device packages that include the MIM capacitors integrated within their package routing/dielectric structure.

In the example illustrated in FIG. 6C, a singulation process 699 cuts through the packaging workpiece between two laterally adjacent IC package structures to singulate individual IC packages 690, each including high-performance MIM capacitors 280. IC packages that integrate a MIM capacitor structure in accordance with one or more of the embodiments described above may be further integrated into a system that includes a host component to which the package routing is attached.

FIG. 6D illustrates a system 650 including IC chip package 690 interconnected to a host component 701, in accordance with some embodiments. In some examples, host component 701 is a PCB, for example including one or more interconnect trace levels laminated with one or more glass-reinforced epoxy sheets, such as, but not limited to FR-4. As depicted in FIG. 6D, IC package 690 includes IC chip 620 interconnected through solder joints 695. IC package 690 further includes high-performance MIM capacitors 280 including a pyrochlore-based insulator material.

Capacitor structures comprising a pyrochlore-based insulator material layer may be incorporated into any IC circuitry or IC die package circuitry that may be singulated from a workpiece following the completion of any conventional processing. With a pyrochlore-based insulator material layer in accordance with embodiments herein, total capacitance of IC die capacitors and IC die package capacitors may be increased substantially.

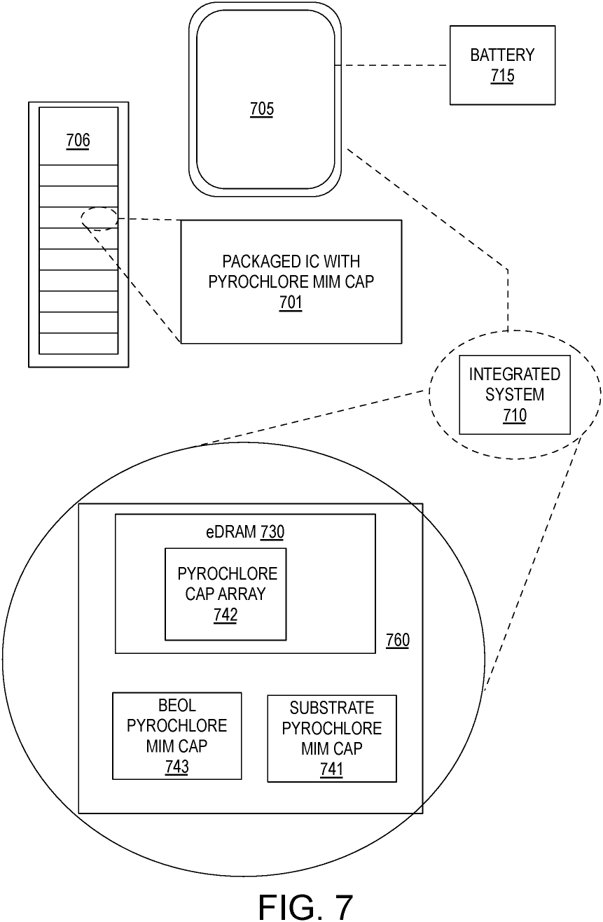

FIG. 7 illustrates a mobile computing platform 705 and a data server computing platform 706 employing a packaged IC including capacitor structures comprising a pyrochlore-based insulator material layer, for example substantially as described elsewhere herein. The server platform 706 may be any commercial server, for example including any number of high-performance computing platforms disposed within a rack and networked together for electronic data processing, which in the exemplary embodiment includes a IC chip 701 including capacitor structures comprising a pyrochlore-based insulator material layer, for example substantially as described elsewhere herein.

The mobile computing platform 705 may be any portable device configured for each of electronic data display, electronic data processing, wireless electronic data transmission, or the like. For example, the mobile computing platform 705 may be any of a tablet, a smart phone, laptop computer, etc., and may include a display screen (e.g., a capacitive, inductive, resistive, or optical touchscreen), a chip-level or package-level integrated system 710, and a battery 715. At least one IC of chip-level or package-level integrated system 710 includes packaged IC includes capacitor structures comprising a pyrochlore-based insulator material layer, for example substantially as described elsewhere herein.

In the example shown in the expanded view, integrated system 710 includes and system-on-chip SOC 760 that includes capacitor structures comprising a pyrochlore-based insulator material layer, for example substantially as described elsewhere herein. For example, SOC 760 includes one or more of a substrate pyrochlore-based MIM cap 741, a BEOL pyrochlore-based MIM capacitor 743 or an eDRAM 730 that includes a pyrochlore MIM capacitor array 742.

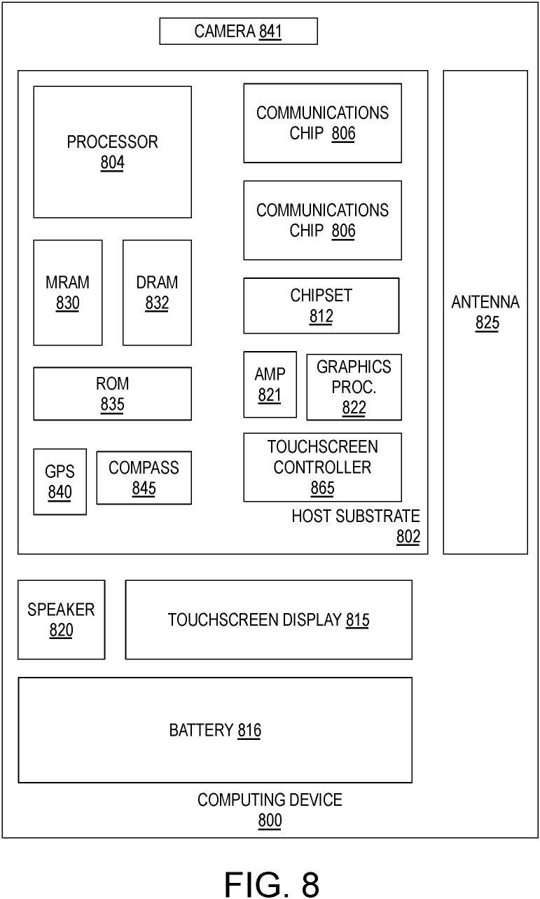

FIG. 8 is a functional block diagram of an electronic computing device 800, in accordance with an embodiment of the present invention. Computing device 800 may be found inside platform 705 or server platform 706, for example. Device 800 further includes a host substrate 802 hosting a number of components, such as, but not limited to, a processor 804 (e.g., an applications processor). Processor 804 may be physically and/or electrically coupled to host substrate 802. In some examples, processor 804 includes capacitor structures comprising a pyrochlore-based insulator material layer, for example substantially as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 806 may also be physically and/or electrically coupled to the host substrate 801. In further implementations, communication chips 806 may be part of processor 804. Depending on its applications, computing device 800 may include other components that may or may not be physically and electrically coupled to host substrate 801. These other components include, but are not limited to, volatile memory (e.g., DRAM 832), non-volatile memory (e.g., ROM 835), flash memory (e.g., NAND or NOR), magnetic memory (MRAM 830), a graphics processor 822, a digital signal processor, a crypto processor, a chipset 812, an antenna 825, touchscreen display 815, touchscreen controller 865, battery 816, audio codec, video codec, power amplifier 821, global positioning system (GPS) device 840, compass 845, accelerometer, gyroscope, speaker 820, camera 841, and mass storage device (such as hard disk drive, solid-state drive (SSD), compact disk (CD), digital versatile disk (DVD), and so forth), or the like. In some exemplary embodiments, at least one of the functional blocks noted above include interconnect structures with low via resistance, for example as described elsewhere herein.

Communication chips 806 may enable wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 806 may implement any of a number of wireless standards or protocols, including but not limited to those described elsewhere herein. As discussed, computing device 800 may include a plurality of communication chips 806. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

It will be recognized that the invention is not limited to the embodiments so described, but can be practiced with modification and alteration without departing from the scope of the appended claims. For example, the above embodiments may include specific combinations of features as further provided below.

In first examples, an integrated circuit (IC) comprises and one or more levels of interconnect metallization electrically coupled to the capacitor through the first or second electrode material layers. The capacitor comprises a first electrode material layer, a second electrode material layer, and an insulator material layer between the first electrode material layer and the second electrode material layer. Thee insulator material layer comprises primarily oxygen (O), a species A comprising one or more first rare-earths or metals, and a species B comprising one or more second rare-earths or metals. An atomic ratio of A:O is less than 1:3 and an atomic ratio B:O is also less than 1:3;

In second examples, for any of the first examples the atomic ratio of A:O and the atomic ratio B:O are each larger than 1:4.

In third examples, for any of the first through second examples the atomic ratio of A:O is approximately equal to the atomic ratio B:O.

In fourth examples, for any of the first through third examples the atomic ratio of A:O and the atomic ratio B:O are each substantially 2:7.

In fifth examples, for any of the first through fourth examples the insulator material layer has a relative permittivity of at least 50.

In sixth examples, for any of the fifth examples the insulator material layer has a relative permittivity of at least 100.

In seventh examples, for any of the first through sixth examples the insulator material layer is substantially amorphous.

In eighth examples, for any of the first through seventh examples the insulator material layer comprises one or more crystalline phases.

In ninth examples, for any of the eighth examples the crystalline phases comprise a pyrochlore crystal structure.

In tenth examples, for any of the first through ninth examples A or B comprises Bi, Zn or Nb.

In eleventh examples, for any of the tenth examples at least one of A or B comprises Mg, Cu, Ni, Sc, In or Ta.

In twelfth examples, for any of the tenth examples both of A and B comprises Bi, Zn or Nb.

In thirteenth examples, for any of the tenth examples at least one of A or B comprises two of Bi, Zn or Nb.

In fourteenth examples, for any of the thirteenth examples A comprises Bi and wherein B comprises two or more of Ng, Cu, Zn, Sc, In, Nb, or Ta.

In fifteenth examples a device comprises an integrated circuit (IC) die, and a package coupled to the IC die. At least one of the IC die or the package comprises a metal-insulator-metal (MIM) capacitor. The MIM capacitor comprises a first electrode material layer, a second electrode material layer, and an insulator material layer between the first electrode material layer and the second electrode material layer. The insulator material layer comprises primarily oxygen (O), species A comprising one or more first rare earths or metals, and species B comprising one or more second rare earths or metals. An atomic ratio of A:O is less than 1:3 and an atomic ratio B:O is also less than 1:3.

In sixteenth examples, for any of the fifteenth examples the IC die comprises a plurality of transistor interconnected by one or more levels of metallization, and the MIM capacitor is over at least one of the levels of interconnect metallization.

In seventeenth examples, for any of the fifteenth through sixteenth examples the IC die comprises an array of the MIM capacitors, and the first electrode material layer is coupled to an access transistor.

In eighteenth examples, for any of the fifteenth examples the package comprises the MIM capacitor, and the first electrode material layer is embedded with an organic dielectric material.

In nineteenth examples, for any of the fifteenth through eighteenth examples the device further comprises a power supply coupled to the package to power the IC die.

In twentieth examples, a method of fabricating an integrated circuit (IC) comprises receiving a substrate comprising a first electrode material layer, and depositing an insulator material layer on the first electrode material layer. The insulator layer comprises primarily oxygen (O), a species A comprising one or more first rare earths or metals, and a species B comprising one or more second rare earths or metals,. An atomic ratio of A:O is less than 1:3 and an atomic ratio B:O is also less than 1:3. The method comprises depositing a second electrode material layer on the insulator layer, and forming one or more levels of interconnect metallization electrically coupled to the first or second electrode material layers.

In twenty-first examples, for any of the twentieth examples depositing the insulator layer further comprises sputtering a target comprising the insulator material layer.

In twenty-second examples, for any of the twentieth examples depositing the insulator layer further comprises an atomic layer deposition (ALD) or metal-organic chemical vapor deposition (MOCVD).

In twenty-third examples, for any of the twenty-second examples depositing the insulator layer further comprises depositing a laminate of a bilayers, each of the bilayers comprising an oxide of species A and an oxide of species B.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

What is claimed is:

1. An integrated circuit (IC), comprising:
a capacitor, comprising:
a first electrode material layer;
a second electrode material layer; and
an insulator material layer between the first electrode material layer and the second electrode material layer, wherein the insulator material layer comprises primarily oxygen (O), a species A comprising one or more first rare-earths or metals, and a species B comprising one or more second rare-earths or metals, and wherein an atomic ratio of A:O is less than 1:3 and an atomic ratio B:O is also less than 1:3; and
one or more levels of interconnect metallization electrically coupled to the capacitor through the first or second electrode material layers.

2. The IC of claim 1, wherein the atomic ratio of A:O and the atomic ratio B:O are each larger than 1:4.

3. The IC of claim 1, wherein the atomic ratio of A:O is approximately equal to the atomic ratio B:O.

4. The IC of claim 3, wherein the atomic ratio of A:O and the atomic ratio B:O are each substantially 2:7.

5. The IC of claim 1, wherein the insulator material layer has a relative permittivity of at least 50.

6. The IC of claim 5, wherein the insulator material layer has a relative permittivity of at least 100.

7. The IC of claim 1, wherein the insulator material layer is substantially amorphous.

8. The IC of claim 1, wherein the insulator material layer comprises one or more crystalline phases.

9. The IC of claim 8, wherein the crystalline phases comprise a pyrochlore crystal structure.

10. The IC of claim 1, wherein A or B comprises Bi, Zn or Nb.

11. The IC of claim 10, wherein at least one of A or B comprises Mg, Cu, Ni, Sc, In or Ta.

12. The IC of claim 10, wherein both of A and B comprises Bi, Zn or Nb.

13. The IC of claim 10, wherein at least one of A or B comprises two of Bi, Zn or Nb.

14. The IC of claim 13, wherein A comprises Bi and wherein B comprises two or more of Ng, Cu, Zn, Sc, In, Nb, or Ta.

15. A device comprising:
an integrated circuit (IC) die; and
a package coupled to the IC die, wherein at least one of the IC die or the package comprises
a metal-insulator-metal (MIM) capacitor, wherein the MIM capacitor comprises:
a first electrode material layer;
a second electrode material layer; and
an insulator material layer between the first electrode material layer and the second electrode material layer, wherein the insulator material layer comprises primarily oxygen (O), species A comprising one or more first rare earths or metals, and species B comprising one or more second rare earths or metals, and wherein an atomic ratio of A:O is less than 1:3 and an atomic ratio B:O is also less than 1:3.

16. The device of claim 15, wherein:
the IC die comprises a plurality of transistor interconnected by one or more levels of metallization; and
the MIM capacitor is over at least one of the levels of interconnect metallization.

17. The device of claim 15, wherein:
the IC die comprises an array of the MIM capacitors; and
the first electrode material layer is coupled to an access transistor.

18. The device of claim 15, wherein:
the package comprises the MIM capacitor; and
the first electrode material layer is embedded with an organic dielectric material.

19. The device of claim 15, further comprising a power supply coupled to the package to power the IC die.

20. A method of fabricating an integrated circuit (IC), the method comprising:
receiving a substrate comprising a first electrode material layer;
depositing an insulator material layer on the first electrode material layer, wherein the insulator layer comprises primarily oxygen (O), a species A comprising one or more first rare earths or metals, and a species B comprising one or more second rare earths or metals, and wherein an atomic ratio of A:O is less than 1:3 and an atomic ratio B:O is also less than 1:3;
depositing a second electrode material layer on the insulator layer; and
forming one or more levels of interconnect metallization electrically coupled to the first or second electrode material layers.

21. The method of claim 20, wherein depositing the insulator layer further comprises
sputtering a target comprising the insulator material layer.

22. The method of claim 20, wherein depositing the insulator layer further comprises an atomic layer deposition (ALD) or metal-organic chemical vapor deposition (MOCVD).

23. The method of claim 22, wherein depositing the insulator layer further comprises
depositing a laminate of a bilayers, each of the bilayers comprising an oxide of species A and an oxide of species B.
